(19) United States
(12) Patent Application Publication
(10) Pub. No.: US 2006/0273342 A1
(43) Pub. Date: Dec. 7, 2006

(54) GaN-series of light emitting diode with high light extraction efficiency

(76) Inventors: Mu-Jen Lai, Pingjhen City (TW); Schang-Jing Hon, Pingjhen City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/501,773

(22) Filed: Aug. 10, 2006

Related U.S. Application Data
(63) Continuation-in-part of application No. 10/950,132, filed on Sep. 27, 2004.

(30) Foreign Application Priority Data
Nov. 25, 2003 (TW) 92132987

(51) Int. Cl. H01L 33/00

(52) U.S. Cl. 257/103; 257/E33.033

(57) ABSTRACT

A GaN-series of light emitting diode with high light extraction efficiency includes a substrate, a n-type semiconductor, a light emitting layer and a p-type semiconductor layer. More particular, the p-type semiconductor layer includes a p-type cladding layer, a p-type transition layer and a p-type ohmic contact layer, wherein the p-type transition layer is formed on the p-type cladding layer and the p-type ohmic contact layer is formed on the p-type transition layer. A doping concentration of magnesium of the p-type ohmic contact layer is between the p-type cladding layer and the p-type transition layer thereof that is to form the strain among three layers of the p-type semiconductor layer. Hence, a surface (the p-type ohmic contact layer) of the p-type semiconductor layer has a non-hexagonal texture, which interruptes the optical waveguide effect to increase external quantum efficiency and operation life of the light emitting diode.

### REFERENCE TO RELATED APPLICATIONS

This is a Continuation-in-Part of patent application Ser. No. 10/950,132 filed 27 Sep. 2004, now pending.

### BACKGROUND OF THE INVENTION

1. Field of the Invention

The present invention relates to a GaN-series of light emitting diode with high light extraction efficiency, especially to a GaN-series of light emitting diode, which comprises a semiconductor surface with a non-hexagonal texture structure by controlling the strain of epitaxy layers during the process of epitaxial growth for interrupting the optical waveguide effect.

2. Description of the Related Art

A GaN-series of the light emitting diode in the prior art shows in FIG. 1, which is so-called conventional structure. The GaN-series of the light emitting diode comprises a GaN buffer layer 2, a n-type GaN ohmic contact layer 3, a InGaN light emitting layer 4, a p-type AlGaN cladding layer 5 and a p-type GaN ohmic contact layer 6. The above-mentioned layers grows sequentially on the sapphire substrate 1, wherein making a semi-transparent metal conductive layer 7 on the p-type GaN ohmic contact layer 6, and making a p-side electrode 8 on the p-type GaN ohmic contact layer 6 and making a n-side electrode 9 on the GaN ohmic contact 3. Because the refraction index of a plurality of the GaN epitaxial layers is 2.4, the refraction index of sapphire substrate is 1.77 and the refraction index of resin capping materials for packaging is 1.5, only 25% of light emits from the light emitting layer and outputs directly and not be reflected by the interface. The rest of 75% of light are limited by the optical waveguide structure, which is composed of the sapphire substrate and resin capping materials for packaging. The rest of 75% of light increases the probabilities of light reabsorption through several times interface reflection so can't be outputted and utilized efficiently.

In order to improve the light extraction efficiency of the light emitting diode in above mentioned, please refer to the U.S. Pat. No. 6,091,085, which discloses a method of interrupting the optical waveguide effect. The method is firstly generating a rough texture on the surface of sapphire substrate by roughening and then grown multi-layers epitaxial structure of GaN-series of light emitting diode. Also, the roughening can result in imperfections in the top surface of the GaN to form the rough texture, which provides a significant improvement in the light extraction efficiency without altering the surface features of the light emitting diode. The method of roughening is etching, which can be carried out by lithographically defining openings using photoresist and then using the photoresist as an etch mask. The etching can be performed by any of a number of conventional methods such as ion etching, ion milling, or H₃ PO₄. The other method is to directly grow the epitaxial structure of GaN-series of light emitting diode on the sapphire substrate, and then directly produce tunnel channels on the surface of epitaxial structure. The tunnel channels extends to the direction of sapphire substrate and is embedded with the materials whose refraction index is smaller than the one (n=2.4) of multi-layer GaN epitaxial structure.

However, the method one requires utilizing a method of mechanical polishing or chemical etching to produce the rough texture so it easily causes the non-uniformity of surface roughness on the sapphire substrate and then influences the conditions of next epitaxial structure and also not easily to control the manufacturing yield. Besides, the method two increases the complexity of fabrication and manufacturing cost because of making tunnel channels and embedded materials.

Furthermore, the U.S. Pat. No. 6,495,862 discloses that a convexity surface of GaN-series of light emitting diode which can increase the light extracted from the light emitting layer. But the complexity of fabrication and manufacturing cost are increased in order to make the surface with cylindrical or semi-circle convex texture and the ohmic contact property is difficult to control stably.

Moreover, the U.S. Pat. No. 6,531,719 discloses a method, which interrupts the optical waveguide effect and reduces flexural distortion of epitaxial chip generated from stress. The method utilized the conditions of epitaxial growth to grow the internal layer of AlN, which has reticulate linear structure and is located between the light emitting layer and the sapphire substrate to interrupt the optical waveguide effect and increase external quantum efficiency. Moreover, a metal reflection layer is formed on the AlN internal layer to reflect the light from the light emitting layer directing to the sapphire substrate for increasing external quantum efficiency. This patent discloses that injecting ammonia gas (NH3) and trimethyalumium (TMA) into reaction chamber and controlling the flow of ammonia gas, while the internal layer of AlN is grown by utilizing the metal organic chemical vapor deposition (MOCVD) to control the reticulate linear shape and then growing other multi-layers epitaxial structure. However, this method easily forms the hexagonal shaped pits according to the thesis (APL 71, (9), September 1 (1997), p. 1204). If the pits very easily extends to the surface of p-type ohmic contact layer from the internal layer of AlN, the pits will cause the metal atoms to diffuse into the light emitting layer to disrupt the characteristics of light emitting diode device and shorten the operation life of device when the consecutive semi-transparent conductive metal layer or metal electrode being produced.

According to the thesis of J. L. Rouviere et al (Journal of Nitride-Semiconductor-Research, Vol. 1, (1996) Art. 33) illustrates that the shape of surface presents three types of hexagonal pyramid shaped roughness, flat, and granular roughness in accordance with the different conditions of epitaxial growth, while the thin film of GaN is grown on the sapphire substrate by using MOCVD skill. The experiment proves that the presented shaped of surface is determined by the polarization direction and migration rate of surface atoms. When the growth mechanism of surface is mainly controlled by the N-polarity, the surface shape is roughness; when the growth mechanism of surface is mainly controlled by the Ga-polarity, the surface shape is flat and when the surface of GaN thin film is flat, the occurring possibility of hexagonal shaped pits is reduced and even disappeared.

Therefore, providing a novel of GaN-series of light emitting diode with high light extraction efficiency and its manufacturing method thereof can eliminate the drawbacks from the prior arts (such as mechanical polishing or chemical etching) to interrupt the optical waveguide effect. Based on the inventor engaging on the research and developing and sales experiences for the related products for many years, the inventor finally proposes a method to solve the aforementioned problems for improving a high light efficiency of GaN-series of light emitting diode and its manufacturing method thereof according to his professional background.

### SUMMARY OF THE INVENTION

The first purpose of the present invention is to provide a GaN-series of light emitting diode with high light extraction efficiency, which comprises a substrate and a semiconductor having a n-type semiconductor, a light emitting layer and a p-type semiconductor layer, wherein a polarity surface (the p-type ohmic contact layer) of the p-type semiconductor layer has a non-hexagonal texture figure thereon to interrupt the optical waveguide effect and increases external quantum efficiency of the light emitting diode.

The second purpose of the present invention is to provide a GaN-series of light emitting diode with high light extraction efficiency, more particular to a p-type semiconductor layer having a p-type cladding layer, a p-type transition layer and a p-type ohmic contact layer, wherein a doping concentration of magnesium of the p-type ohmic contact layer is between the p-type cladding layer and the p-type transition layer thereof. Hence, the strain effect among above three layers of the p-type semiconductor layer causes the non-hexagonal texture generated on the surface of the p-type semiconductor.

The third purpose of the present invention is to provide a GaN-series of light emitting diode with high light extraction efficiency, more particular to at least one monolayer of atoms selected from gallium, indium, silicon, magnesium or aluminum on the p-type cladding layer and at least one monolayer of atoms selected from gallium, indium, silicon, magnesium or aluminum on the p-type transition layer. Hence, the strain among above three layers of the p-type semiconductor layer is altered to cause the polarization inversion, then form the non-hexagonal texture generated on the surface of the p-type semiconductor.

### BRIEF DESCRIPTION OF THE DRAWINGS

FIG. 1 is a sectional view showing a light emitting diode of prior art.

FIG. 2 is a manufacturing flow chart of the GaN-series of light emitting diode with high light extraction efficiency showing a preferred embodiment in the present invention.

FIG. 3 is a perspective view illustrating a preferred embodiment of the GaN-series of light emitting diode with high light extraction efficiency of the present invention.

FIG. 4A˜4E are Scanning Electron Microscopy (SEM) photographs of the texture structure of p-type semiconductor layer surface according to the preferred embodiment of the present invention.

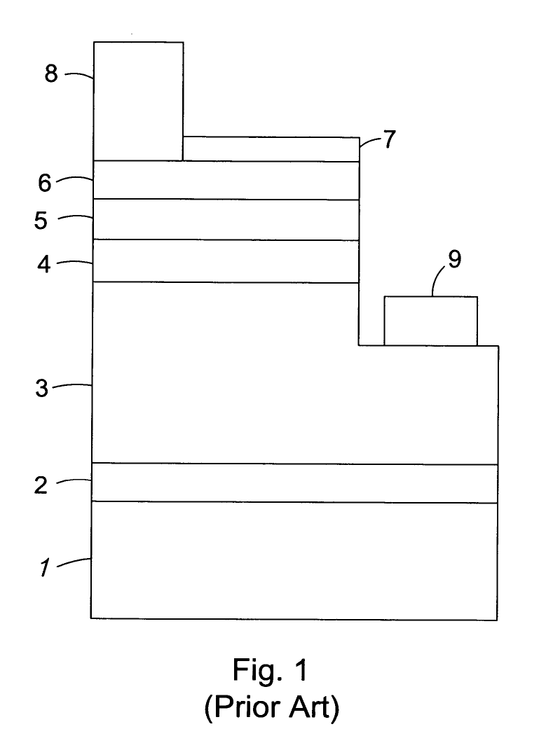

### DETAILED DESCRIPTION OF THE PREFERRED EMBODIMENTS

In order to clearly express the feature characteristics and efficiency of the present invention for the examiner, the preferred embodiment and detailed description is in following content.

The present invention is related to a method and a structure of interrupting optical waveguide effect and aims to solve the prior arts, which are about the post-process, such as mechanical polishing, chemical etching or the metal organic chemical vapor deposition (MOCVD) epitaxy skill to generate the texture surface. The skills of the prior arts easily generate the hexagonal shaped pits to shorten life of light emitting diode. Hence, the process and structure of the present invention are novel arts, which do not require the post-process and do not generate the hexagonal shaped pits.

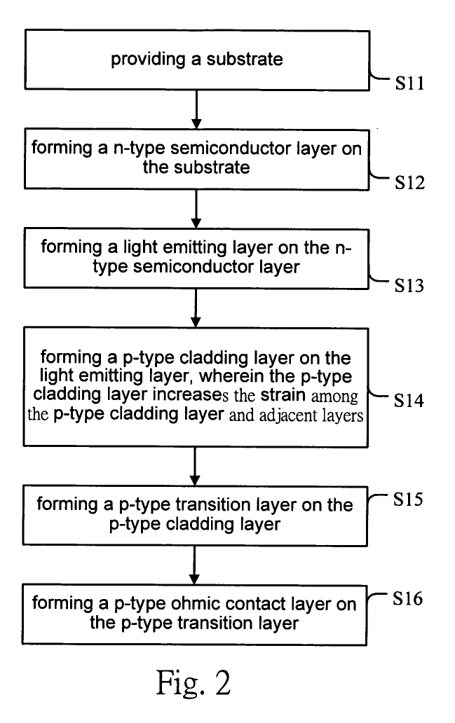

Firstly, please refer to FIG. 2, which illustrates the manufacturing flow chart of the preferred embodiment of the GaN-series of light emitting diode with high light extraction efficiency of the present invention. The manufacturing flow chart comprises the steps of
Step 11: providing a substrate;
Step 12: forming a n-type semiconductor layer on the substrate;
Step 13: froming a light emitting layer on the n-type semiconductor layer;
Step 14: forming a p-type cladding layer on the light emitting layer, wherein the p-type cladding layer increases the strain among the p-type cladding layer and adjacent layers (the strain between the p-type cladding layer and the light emitting layer or between the p-type cladding layer and a p-type transition layer of the following Step 15).
Step 15: forming a p-type transition layer on the p-type cladding layer; and
Step 16: forming a p-type ohmic contact layer on the p-type transition layer.

From step 14 to step 16, a method of the increasing strain of p-type cladding layer and forming a p-type semiconductor layer with texture surface comprises the steps of:
1. P-type cladding layer contains a magnesium (Mg) dopant with high concentration to increase the strain among epitaxial layers. Then, interrupting the growth of epitaxial layers and controlling the interruption time to alter the strain between the epitaxial layers, wherein the interruption time is between one second and two minutes. Next growing a p-type transition layer, which contains a magnesium (Mg) dopant with lower concentration, and lastly growing a p-type ohmic contact layer, which contains a magnesium (Mg) dopant with proper concentration.
2. P-type cladding layer contains a magnesium (Mg) dopant with high concentration to increase the strain among epitaxial layers, then interrupting the epitaxial growth and utilizing the change of temperature to alter the strain among epitaxial layers, wherein the temperature is in a range of from 5° C. to 300° C., next growing a p-type transition layer, which contains a magnesium (Mg) dopant with lower concentration, and lastly growing a p-type ohmic contact layer, which contains a magnesium (Mg) dopant with proper concentration.
3. P-type cladding layer contains a magnesium (Mg) dopant with high concentration to increase the strain among epitaxial layers, then interrupting the epitaxial growth and form at least one monolayer of atoms, which are selected from gallium, indium and aluminum on the surface of p-type cladding layer to alter the strain between the p-type cladding layer 260 and the p-type transition layer 262, wherein the number of monlayer is from one to five, next growing a p-type transition layer, which contains a magnesium (Mg) dopant with lower concentration, and lastly growing a p-type ohmic contact layer, which contains a magnesium (Mg) dopant with proper concentration.
4. Increasing aluminum composition of p-type cladding layer to increase the strain among epitaxial layers, then interrupting the epitaxial growth and controlling the interruption time to alter the strain among the epitaxial layers, wherein the interruption time is between one second to two minutes, next growing a p-type transition layer, which contains a magnesium (Mg) dopant with lower concentration, and lastly growing a p-type ohmic contact layer, which contains a magnesium (Mg) dopant with proper concentration.
5. Increasing aluminum composition of p-type cladding layer to increase the strain among epitaxial layers, then interrupting the epitaxial growth and utilizing the change of temperature to alter the strain among epitaxial layers, wherein the temperature is in a range of from 5° C. to 300° C., next growing a p-type transition layer containing a magnesium (Mg) dopant with lower concentration, and lastly growing a p-type ohmic contact layer, which contains a magnesium (Mg) dopant with proper concentration.
6. Increasing aluminum composition of p-type cladding layer to increase the strain among epitaxial layers, then interrupting the epitaxial growth and form at least one monolayer of atoms, which are selected from gallium, indium and aluminum on the surface of p-type cladding layer to alter the strain between the p-type cladding layer and the p-type transition layer, wherein the number of monlayer is from one to five, next growing a p-type transition layer, which contains a magnesium (Mg) dopant with lower concentration, and lastly growing a p-type ohmic contact layer, which contains a magnesium (Mg) dopant with proper concentration.

Further, the method of forming the p-type transition layer is described as follows.
1. To control a composition of aluminum or a dopant of magnesium among the epitaxy layers to reduce the strain between epitaxial layers and the p-type cladding layer (between the p-type transition layer and p-type cladding layer).
2. To reduce the strain between epitaxial layers and p-type cladding layer(between the p-type transition layer and p-type cladding layer), next to interrupt the growth of epitaxial layers and to control the interruption time to alter the strain among epitaxial layers, wherein the interruption time is in a range of from one second to two minutes.
3. To reduce the strain between epitaxial layers and p-type cladding layer (between the p-type transition layer and p-type cladding layer), next to interrupt the growth of epitaxial layers and to utilize the change of temperature to alter the strain among epitaxial layers, wherein the temperature is in a range of from 5° C. to 300° C.
4. To reduce the strain between epitaxial layers and p-type cladding layer (between the p-type transition layer and p-type cladding layer), next to interrupt epitaxial growth and to form at least one monolayer of atoms, which are selected from gallium, indium, silicon, magnesium and aluminum on the surface of p-type cladding layer to alter the strain between the p-type transition layer and the p-type ohmic contact layer, wherein the number of monolayer is from one to five. The method of forming the p-type ohmic contact layer is to utilize epitaxial growth to increase bis(cyclopentadienyl) magnesium (Cp₂Mg) flow or reduce temperature to increase magnesium doping concentration.

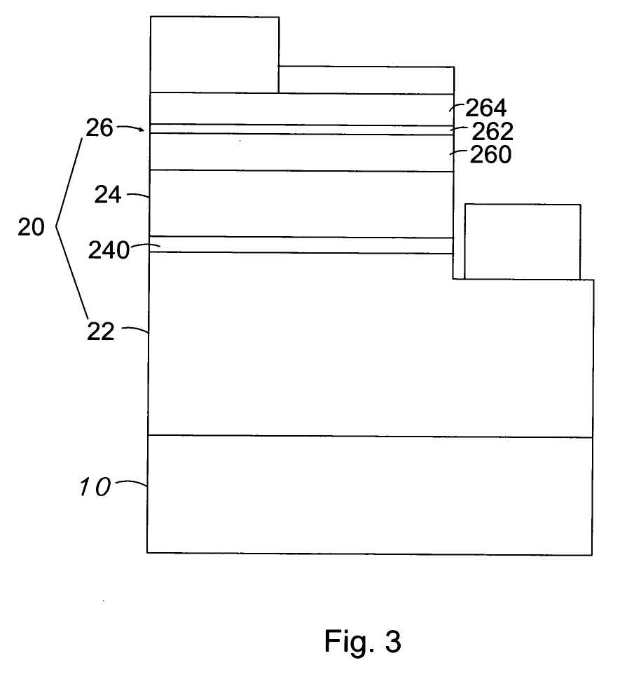

Moreover, please refer to FIG. 3, which is a schematic diagram of a preferred embodiment of light emitting diode of the present invention. FIG. 3 illustrates the main structure of a GaN-series of light emitting diode with high light extraction efficiency, which comprises a substrate 10, the substrate located on the bottom of the light emitting diode device; a semiconductor layer 20 located on the substrate 10 and the semiconductor layer 20 having a n-type semiconductor layer 22, a light emitting layer 24 and a p-type semiconductor layer 26, wherein the light emitting layer 24 is located between the n-type semiconductor layer 22 and the p-type semiconductor layer 26. The p-type semiconductor layer 26 further comprises a p-type cladding layer 260, a p-type transition layer 262 and a p-type ohmic contact layer 264, sequentially growing on the light emitting layer 24. Hence, the p-type cladding layer 260 is formed on the light emitting layer 24 and the p-type transition layer 262 is formed on the p-type cladding layer 260 and the p-type ohmic contact layer 264 is formed on the p-type transition layer 262. The p-type ohmic contact layer 264 also has a polarity inversion surface. At least one monolayer of atoms, are selected from gallium, indium, silicon, magnesium and aluminum on the surface of the p-type cladding layer to alter the strain between the p-type cladding layer 260 and the p-type transition layer 262, wherein the number of monlayer is from one to five. (not show in FIG. 3) Also, at least one monolayer of atoms are selected from gallium, indium, silicon, magnesium and aluminum on the surface of the p-type transition layer 262 to alter the strain between the p-type transition layer 262 and the p-type ohmic contact layer 264, wherein the number of monlayer is from one to five. (not show in FIG. 3) Furthermore, the p-type cladding layer 260 is a cladding layer for increasing the strain. Moreover, the light emitting diode of the present invention further comprises a reflection layer 240, which is located below the light emitting layer 24. The structure of the reflection layer 240 could be a Distributed Bragg Reflector, which is stacked by the semiconductor layers.

The substrate 10 is selected from one of sapphire, silicon carbide, zinc oxide, zirconium diboride, gallium arsenide and silicon and the composition of the n-type semiconductor layer 22 can be represented as N—BₓAl_{y}In_{z}Ga_{1-x-y-z}NₚAs_{q} (0≦x≦1, 0≦y≦1, 0≦z≦1, 0≦p≦1, 0≦q≦1, and x+y+z<1, p+q=1) or N—BₓAl_{y}In_{z}Ga_{1-x-y-z}Nₚ P_{q}. (0≦x≦1, 0≦y≦1, 0≦z≦1, 0≦p≦1, 0≦q≦1, and x+y+z<1, p+q=1) The composition of the p-type semiconductor layer 26 can be represented as P—BₓAl_{y}In_{z}Ga_{1-x-y-z} NₚAs_{q} (0≦x≦1, 0≦y≦1, 0≦z≦1, 0≦p≦1, 0≦q≦1, and x+y+z<1, p+q=1) or P—BₓAl_{y}In_{z} Ga_{1-x-y-z}NₚP_{q}. (0≦x≦1, 0≦y≦1, 0≦z≦1, 0≦p≦1, 0≦q≦1, and x+y+z<1, p+q=1) The light emitting layer 24 can be composed by one of BₓAl_{y}In_{z}Ga_{1-x-y-z}NₚAs_{q} (0≦x≦1, 0≦y≦1, 0≦z≦1, 0≦p≦1, 0≦q≦1, and x+y+z<1, p+q=1) or BₓAl_{y}In_{z}Ga_{1-x-y-z}NₚP_{q}. (0≦x≦1, 0≦y≦1, 0≦z≦1, 0≦p≦1, 0≦q≦1, and x+y+z<1, p+q=1) Also, the light emitting layer 24 can be composed of BₓAl_{y}In_{z}Ga_{1-x-y-z}NₚAs_{q} and BₓAl_{y}In_{z}Ga_{1-x-y-z}Nₚ P_{q} to form a quantum well structure.

Furthermore, the p-type transition layer 262 or the p-type ohmic contact 264 is superlattice structure, which can be stacked by the semiconductor layers with different compositions, different thickness, and different doped concentration.

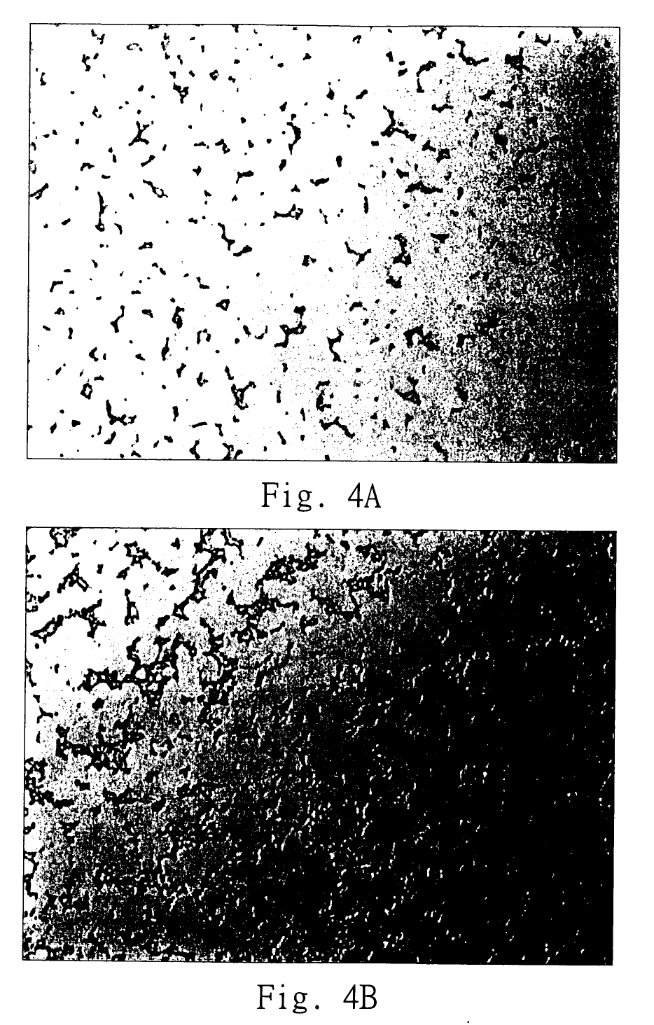

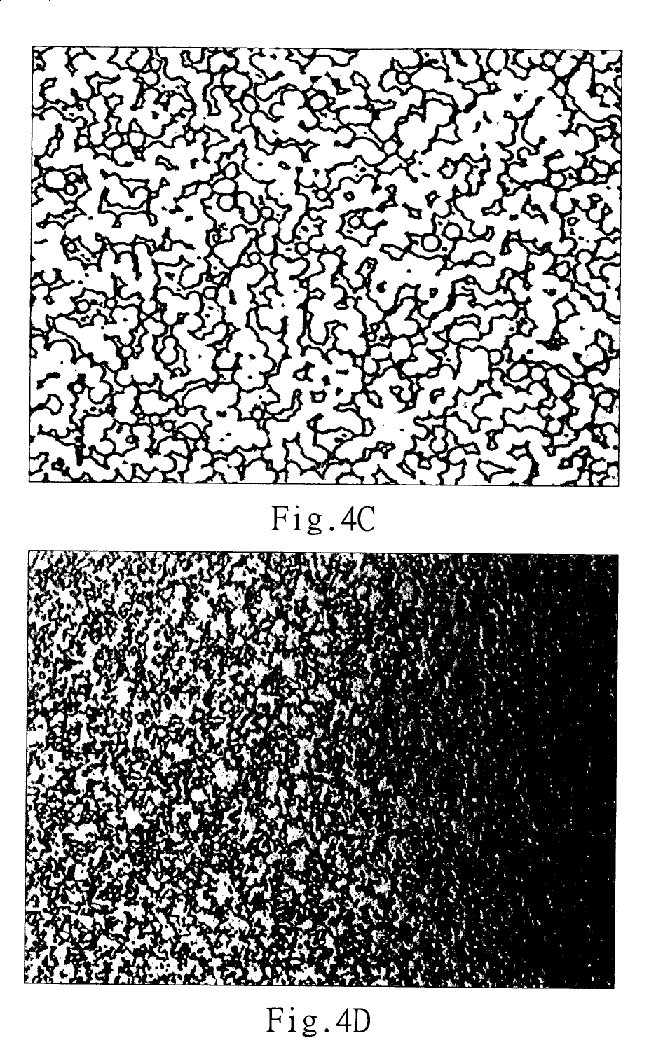

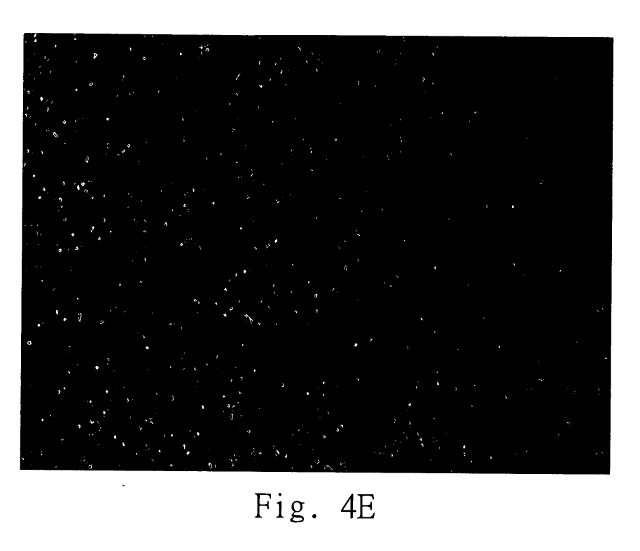

The surface of the p-type semiconductor layer 26 has a non-hexagonal texture, which can interrupt the optical waveguide effect. The p-type cladding layer contains magnesium doping concentration in a range of from 5×10¹⁹ to 5×10²⁰ cm⁻³ and the p-type transition layer contains magnesium doping concentration in a range of from 5×10¹⁷ to 5×10¹⁹ cm⁻³. The magnesium doping concentration of the p-type ohmic contact layer is between the magnesium doping concentration of p-type cladding layer and the magnesium doping concentration of p-type transition layer. The non-hexagonal texture structure of the p-type semiconductor layer is shown from FIG. 4A to 4E, which exhibit the SEM photographs of texture of p-type semiconductor layer of a preferred embodiment in the present invention. The FIG. 4A to 4E illustrate that the non-hexagonal texture is generated during the epitaxial process and is not generated from the post-processes of the prior arts. Therefore, the non-hexagonal texture can be generated during the epitaxial processes to achieve the purpose of interrupting optical waveguide effect.

The present invention is a method of directly controlling the non-hexagonal texture generation without post-processes during manufacturing. The non-hexagonal texture is generated on the p-type semiconductor layer and the non-hexagonal texture is used for light scattering to interrupt optical waveguide effect, which is generated by the substrate and the resin capper material for packaging. The non-hexagonal texture of the p-type semiconductor layer also increases the external quantum efficiency of the light emitting diode and reduces the possibility of hexagonal shaped pits generation and then increases the operation life of light emitting diode device.

While certain preferred embodiments of the present invention have been disclosed in detail, it is to be understood that various modifications may be adopted without departing from the spirit of the invention or scope of the following claims.

What is claimed is:

1. A GaN-series of light emitting diode with high light extraction efficiency comprising:
a substrate; and
a semiconductor formed on the substrate and the semiconductor having a n-type semiconductor, a light emitting layer, a p-type semiconductor layer, wherein the light emitting layer is between the n-type semiconductor layer and the p-type semiconductor layer and n-type semiconductor layer is formed on the substrate;
wherein, a surface of the p-type semiconductor layer has a non-hexagonal texture thereon.

2. The GaN-series of light emitting diode with high light extraction efficiency according to claim 1, wherein an optical waveguide effect is interrupted by the non-hexagonal texture.

3. The GaN-series of light emitting diode with high light extraction efficiency according to claim 1, wherein the p-type semiconductor layer has the non-texture formed by controlling the strain during the epitaxy process of p-type semiconductor layer.

4. The GaN-series of light emitting diode with high light extraction efficiency according to claim 1, wherein the p-type semiconductor layer comprises a p-type cladding layer and a p-type transition layer formed on the p-type cladding layer and a p-type ohmic contact layer formed on the p-type transition layer and the p-type ohmic contact layer has a non-hexagonal textured surface.

5. The GaN-series of light emitting diode with high light extraction efficiency according to claim 1, further comprising a reflection layer below the light emitting layer.

6. The GaN-series of light emitting diode with high light extraction efficiency according to claim 1, wherein the substrate is selected from one of sapphire, silicon carbide, zinc oxide, zirconium diboride, gallium arsenide and silicon.

7. The GaN-series of light emitting diode with high light extraction efficiency according to claim 1, wherein a composition of the n-type semiconductor layer is represented as N—BₓAl_{y}In_{z}Ga_{1-x-y-z}NₚAs_{q} (0≦x≦1, 0≦y≦1, 0≦z≦1, 0≦p≦1, 0≦q≦1, and x+y+z<1, p+q=1) or N—BₓAl_{y}In_{z}Ga_{1-x-y-z}NₚP_{q}. (0≦x≦1, 0≦y≦1, 0≦z≦1, 0≦p≦1, 0≦q≦1, and x+y+z<1, p+q=1)

8. The GaN-series of light emitting diode with high light extraction efficiency according to claim 1, wherein a composition of the p-type semiconductor layer is represented as P—BₓAl_{y}In_{z}Ga_{1-x-y-z}NₚAs_{q} (0≦x≦1, 0≦y≦1, 0≦z≦1, 0≦p≦1, 0≦q≦1, and x+y+z<1, p+q=1) or P—BₓAl_{y}In_{z}Ga_{1-x-y-z}NₚP_{q}. (0≦x≦1, 0≦y≦1, 0≦z≦1, 0≦p≦1, 0≦q≦1, and x+y+z<1, p+q=1)

9. The GaN-series of light emitting diode with high light extraction efficiency according to claim 1, wherein the light emitting is composed of one of BₓAl_{y}In_{z}Ga_{1-x-y-z}NₚAs_{q} (0≦x≦1, 0≦y≦1, 0≦z≦1, 0≦p≦1, 0≦q≦1, and x+y+z<1, p+q=1) or BₓAl_{y} In_{z}Ga_{1-x-y-z}NₚP_{q} (0≦x≦1, 0≦y≦1, 0≦z≦1, 0≦p≦1, 0≦q≦1, and x+y+z<1, p+q=1), or the light emitting is composed of the BₓAl_{y}In_{z}Ga_{1-x-y-z}NₚAs_{q} and the BₓAl_{y}In_{z} Ga_{1-x-y-z}NₚP_{q} to form a quantum well structure.

10. The GaN-series of light emitting diode with high light extraction efficiency according to claim 1, wherein a strain between the p-type cladding layer and the p-type transition layer is altered by interrupt epitaxy growth after the p-type cladding layer.

11. The GaN-series of light emitting diode with high light extraction efficiency according to claim 1, wherein the p-type transition layer is a superlattice structure and the superlattice structure is stacked by the semiconductor layers with different compositions, thickness, and doped concentration.

12. The GaN-series of light emitting diode with high light extraction efficiency according to claim 1, wherein the p-type ohmic contact layer is a superlattice structure and the superlattice structure is stacked by the semiconductor layers with different compositions, thickness, and doped concentration.

13. The GaN-series of light emitting diode with high light extraction efficiency according to claim 4, wherein a doping concentration of magnesium of the p-type cladding layer is in a range of 5×10¹⁹ to 5×10²⁰ cm⁻³.

14. The GaN-series of light emitting diode with high light extraction efficiency according to claim 4, wherein a doping concentration of magnesium of the p-type transition layer is in a range of 5×10¹⁷ to 5×10¹⁹ cm⁻³.

15. The GaN-series of light emitting diode with high light extraction efficiency according to claim 4, wherein a doping concentration of magnesium of the p-type ohmic contact layer is between the p-type cladding layer and the p-type transition layer thereof.

16. The GaN-series of light emitting diode with high light extraction efficiency according to claim 5, wherein the reflection layer is stacked by the semiconductor layers to form a Distributed Bragg Reflector.

17. A GaN-series of light emitting diode with high light extraction efficiency comprising:
a substrate;
a semiconductor formed on the substrate and the semiconductor having a n-type semiconductor, a light emitting layer and a p-type semiconductor layer, wherein the light emitting layer is between the n-type semiconductor layer and the p-type semiconductor layer and n-type semiconductor layer is formed on the substrate; and
a polarity invension surface of the p-type semiconductor layer having a non-hexagonal texture thereon;
wherein, a doping concentration of magnesium of the p-type cladding layer is in a range of 5×10¹⁹ to 5×10²⁰ cm⁻³ and a doping concentration of magnesium of the p-type transition layer is in a range of 5×10¹⁷ to 5×10¹⁹ cm⁻³ and a doping concentration of magnesium of the p-type ohmic contact layer is between the p-type cladding layer and the p-type transition layer thereof.

18. A GaN-series of light emitting diode with high light extraction efficiency comprising:
a substrate;
a semiconductor formed on the substrate and the semiconductor having a n-type semiconductor, a light emitting layer and a p-type semiconductor layer, wherein the light emitting layer is between the n-type semiconductor layer and the p-type semiconductor layer and n-type semiconductor layer is formed on the substrate; and
a polarity invension surface of the p-type semiconductor layer having a non-hexagonal texture thereon;
wherein, at least one monolayer of atoms selected from gallium, indium or aluminum on the p-type cladding layer and at least one monolayer of atoms selected from gallium, indium or aluminum on the p-type transition layer.
